(19) United States
(12) Patent Application Publication
(10) Pub. No.: US 2009/0185648 A1
(43) Pub. Date: Jul. 23, 2009

(54) METHODS AND DEVICES FOR PROCESSING SIGNALS TRANSMITTED VIA COMMUNICATION SYSTEM

(76) Inventor: Guo-Hau Gau, Tainan County (TW)

Correspondence Address: NORTH AMERICA INTELLECTUAL PROPERTY CORPORATION, P.O. BOX 506, MERRIFIELD, VA, 22116, US

(21) Appl. No.: 12/017,344

(22) Filed: Jan. 22, 2008

(51) Int. Cl. H03D 1/06

(52) U.S. Cl. 375/346; 375/260

(57) ABSTRACT

A method for processing signals transmitted via a communication system includes: measuring a first parameter associated with a signal power of a first frequency band of a received signal; measuring a second parameter associated with a signal power of a second frequency band of the received signal, wherein the first frequency band and the second frequency band are overlapped; comparing the first parameter with the second parameter to generate a comparison result; and detecting whether co-channel interference (CCI) exists in the communication system according to the comparison result in order to generate a detection result.

### BACKGROUND OF THE INVENTION

1. Field of the Invention

The present invention relates to processing signals transmitted via a communication system, and more particularly, to methods and devices for detection of co-channel interference (CCI) in a Digital Video Broadcasting (DVB) system.

2. Description of the Prior Art

Due to sharing the same frequency band with a conventional television broadcasting system such as the National Television System Committee (NTSC) system, the Digital Video Broadcasting (DVB) system may encounter the problem of co-channel interference (CCI). To counter the effect of the CCI signal, CCI filters are essential in the receiver of the DVB system.

A well-designed CCI filter can effectively eliminate the interference; however, when CCI is absent or negligible, the information carried by subcarriers may be filtered out and hence the performance of the receiver will deteriorate. Since the occurrence of the CCI is volatile in the DVB system, enabling the CCI filter continuously may degrade the system performance when CCI is absent or negligible. Therefore, a novel mechanism of detecting CCI occurrence should be devised to control the operation of the CCI filter according to the existence of CCI to thereby improve the system performance.

### SUMMARY OF THE INVENTION

It is therefore one of the objectives of the claimed invention to provide methods and devices for processing signals transmitted via a communication system to solve the above-mentioned problems.

According to one embodiment of the claimed invention, a method for processing signals transmitted via a communication system is disclosed. The method comprises: measuring a first parameter associated with a signal power of a first frequency band of a received signal; measuring a second parameter associated with a signal power of a second frequency band of the received signal, wherein the first frequency band and the second frequency band are overlapped; comparing the first parameter with the second parameter to generate a comparison result; and detecting whether co-channel interference (CCI) exists in the communication system according to the comparison result in order to generate a detection result.

In addition to the method mentioned above, a device for processing signals transmitted via a communication system is further disclosed according to one embodiment of the claimed invention. The device comprises: a first evaluation unit for measuring a first parameter associated with a signal power of a first frequency band of a received signal; a second evaluation unit for measuring a second parameter associated with a signal power of a second frequency band of the received signal, wherein the first frequency band and the second frequency band are overlapped; a comparator, coupled to the first evaluation circuit and the second evaluation circuit, for comparing the first parameter with the second parameter to generate a comparison result; and a decision unit, coupled to the comparator, for detecting whether CCI exists in the communication system according to the comparison result in order to generate a detection result.

According to yet another embodiment of the claimed invention, a device for processing signals transmitted via a communication system is provided. The device includes: a decision logic, for detecting whether co-channel interference (CCI) exists in the communication system to generate a detection result in a frequency domain; and a controller, coupled to the decision unit, for generating an output signal by selectively enabling or disabling a CCI filtering operation for filtering out the CCI of a received signal according to the detection result.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a block diagram of a signal processing circuit for detecting co-channel interference (CCI) in a DVB receiver according to a first embodiment of the invention.

FIG. 2 illustrates output of an OFDM symbol of an FFT unit shown in FIG. 1.

FIG. 3 illustrates a block diagram of a signal processing circuit for detecting the CCI in a DVB receiver according to a second embodiment of the invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

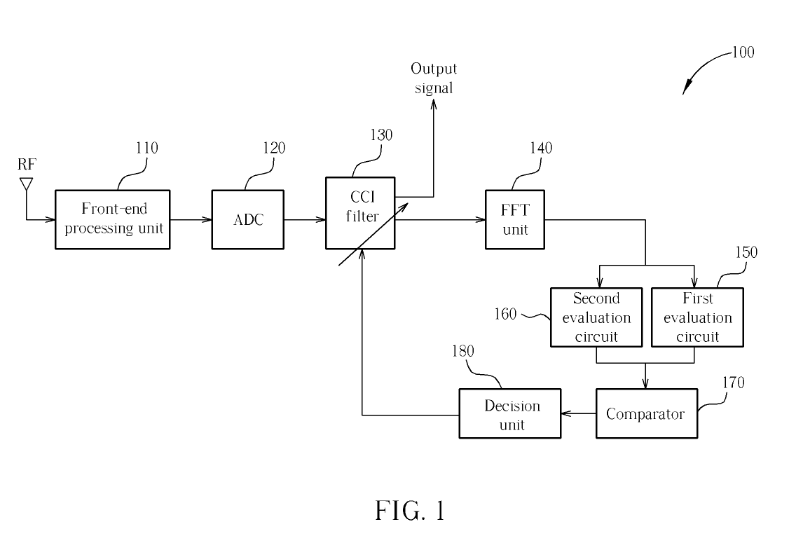

Please refer to FIG. 1. FIG. 1 illustrates a block diagram of a signal processing circuit for detecting co-channel interference (CCI) in a Digital Video Broadcasting (DVB) receiver according to a first embodiment of the invention. The signal processing circuit 100 comprises a first evaluation circuit 150, a second evaluation circuit 160, a comparator 170, and a decision unit 180. As shown in FIG. 1, the received DVB signal will first be converted to a baseband signal by the front-end processing unit 110 (through quadrature-mixing and low-pass filtering, which are well known techniques in the art). The baseband signal is then sampled and digitized using an analog-to-digital converter (ADC) 120; and the digitized signal is then inputted into a controllable CCI filter 130. In this exemplary embodiment, the controllable CCI filter 130 is initially turned off and is not turned on until the CCI is detected. The signal bypassed by the controllable CCI filter 130 is then converted to the frequency domain by the Fast Fourier Transform (FFT) unit 140. Since the DVB system adopts the Orthogonal Frequency Division Multiplexing (OFDM) technique, the FFT algorithm has to be used to convert the received DVB signal to the frequency domain. That is, the received DVB signal includes a plurality of OFDM symbols, and each OFDM symbol has information transmitted via a plurality of orthogonal subcarriers. Therefore, the typical OFDM signals have to be detected and processed using the FFT algorithm.

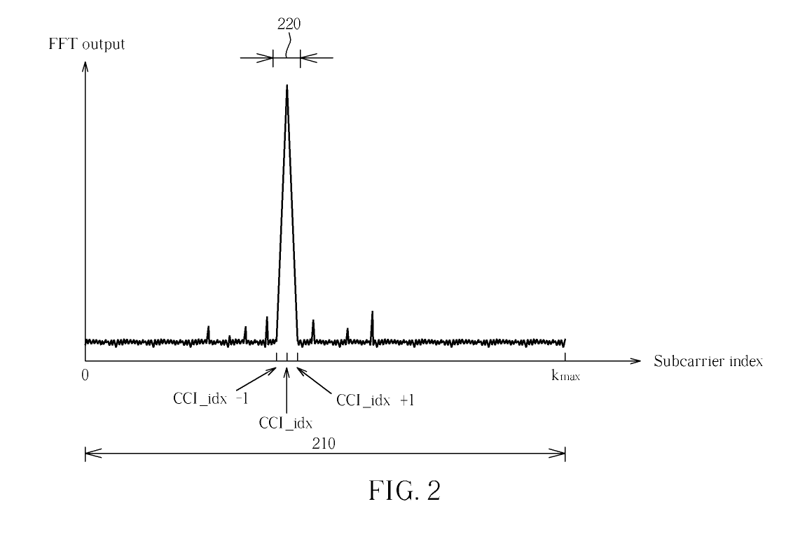

Please refer to FIG. 1 in conjunction with FIG. 2. FIG. 2 illustrates the output of an OFDM symbol of the FFT unit 140 shown in FIG. 1. As shown in FIG. 2, the signal components within a range 210 represent the whole DVB signal and the signal components within the range are affected by CCI. In addition, the range 210 having the subcarrier indexes 0-kₘₐₓ included therein represents a frequency band of the whole DVB signal, while the other range 220 delimited by the subcarrier indexes CCI_idx−1 and CCI_idx+1 represents a specified frequency band where CCI occurs. Please note that in the present invention, kₘₐₓ represent the maximum subcarrier index respectively used in the receiver according to different modes, such as 2K mode, 4 k mode, or 8 k mode of Digital Video Broadcasting-Terrestrial (DVB-T) system. That is, in 2 k mode, kₘₐₓ is equal to 1704; in 4 k mode, kₘₐₓ is equal to 3408; and in 8 k mode, kₘₐₓ is equal to 6816. In addition, CCI_idx in FIG. 2 represents a specified subcarrier index which is most affected by CCI in the DVB signal. It should be noted that signal components belonging to the range 220 delimited by the subcarrier indexes CCI_idx−1 and CCI_idx+1 is a portion of the whole DVB signal 210, and these two frequency bands, corresponding to the DVB signal and the CCI signal, are therefore overlapped. As the technique of OFDM is well known to those skilled in the pertinent art, related details are not repeated here for the sake of brevity.

To detect the CCI signal, measuring the signal power of the received signal is an efficient manner to determine whether the CCI occurs. As known to those skilled in the art, in the frequency domain, the greater is the absolute value of a signal component at a specific frequency, the stronger the signal power of the signal component at the specific frequency is. In general, the signal power is estimated by computing a root mean square of a plurality of signal components over a frequency band. However, in this embodiment, a parameter indicative of the signal power is simply estimated by means of computing the summation of the absolute values of frequency components of a specific signal (e.g., DVB signal or CCI signal) over a specific frequency band.

Hence, for detecting the CCI occurrence, the first evaluation circuit 150 is configured to output a parameter MAG_{CCI}, which is associated with the signal power of the CCI signal having signal components in the range 220 shown in FIG. 2 in which CCI would occur. In addition, the second evaluation circuit 160 is configured to output a parameter MAG_{DVB}, which is associated with the signal power of the frequency band of the received DVB signal (i.e., signal components in the range 210 shown in FIG. 2). As stated above, in this embodiment, the method of calculating a parameter associated with the signal power is by summing the absolute value of the output of the FFT unit 140 over an observed OFDM symbol length L, the disclosed functions are illustrated as below:

MAG_{CCI}=Σ_{s=0˜L} Σ_{k=0˜kmax} Aabs(Y_{s,k}) (1)

MAG_{DVB}=[Σ_{s=0˜L} Σ_{k=CCI}_{_{—}}_{idx-1˜CCI}_{_{—}}_{idx+1} Aabs (Y_{s,k})]/N (2)

where,

MAG_{CCI}: parameter associated with the signal power of the CCI signal;

MAG_{DVB}: parameter associated with the signal power of the received DVB signal;

Y_{s,k}: k^{th} FFT output of the s^{th} OFDM symbol;

s: OFDM symbol index;

k: subcarrier index;

L: observed OFDM symbol length;

N: FFT sampling points (for 2K mode, N=2048; for 4K mode, N=4096; for 8K mode, N=8192);

Aabs( ): a simplified absolute value function;

Kₘₐₓ: maximum subcarrier index (for 2K mode, Kₘₐₓ=1704; for 4K mode, Kₘₐₓ=3408; for 8K mode, Kₘₐₓ=6816); and

CCI_idx: subcarrier index mainly affected by CCI.

Since the FFT output is a complex number, the absolute value of the k^{th} FFT output of the s^{th} OFDM symbol (i.e., Y_{s,k}) can be directly obtained through computing the square root of Re(Y_{s,k}) and Im(Y_{s,k}), i.e., {square root over ((Re(Ys,k))²+(Im(Ys,k))²)}. Please note that Re(Y_{s,k}) and Im(Y_{s,k}) respectively represent the real part and imaginary part of Y_{s,k}. However, to simplify the computational complexity, the present invention employs a simplified absolute value function Aabs(.) to obtain an approximate value of above-mentioned square root of Re(Y_{s,k}) and Im(Y_{s,k}). For example, in one implementation, regarding a complex number A+Bi, Aabs(A+Bi) can be easily obtained using max {|A|, |B|}+½ min {|A|,|B|}. However, this is for illustrative purposes only, and is not meant to be a limitation of the present invention. Other computation algorithms can also be employed to define this simplified absolute value function, depending upon design requirements. Furthermore, if the first and second evaluation circuits 150 and 160 are equipped with powerful computation capability, a more complicated absolute value function can be employed for obtain parameters more accurately indicating the signal power of the DVB signal and CCI signal. This also obeys the spirit of the present invention.

The comparator 170 then compares the two parameters MAG_{DVB} and MAG_{CCI} to generate a comparison result R by estimating a ratio of MAG_{CCI} to MAG_{DVB}, as below:

R=MAG_{CCI}/MAG_{DVB} (3)

The decision unit 180 is implied to detect the CCI existence according to the comparison result R to generate a detection result. The decision rule is as follows:

If R (i.e., MAG_{CCI}/MAG_{DVB})≦CCI_thrd, then CCI is absent;

If R (i.e., MAG_{CCI}/MAG_{DVB})>CCI_thrd, then CCI exists.

If the comparison result R is not greater than or equal to a predetermined threshold CCI_thrd, the decision unit 180 accordingly determines the absence of CCI and generates a detection signal to the controllable CCI filter 130 for turning off the CCI filter 130. Otherwise, if the comparison result R is greater than the predetermined threshold CCI_thrd, the decision unit 180 determines that CCI occurs and therefore generates a detection signal to the controllable CCI filter 130 for turning on the CCI filter 130. Through the detection result R generated by the decision unit 180, an output signal is outputted from the CCI filter 130 by selectively enabling or disabling a CCI filtering operation for filtering out the CCI.

Here please note that the first parameter MAG_{CCI}, and the second parameter MAG_{DVB} are respectively parameters associated with a power intensity of a specified signal band (i.e., signal band of CCI signal or DVB signal); these two parameters do not express the precise signal power of the aforementioned signal band. The parameter R is also a parameter for illustrating only. The magnitude of these three parameters MAG_{CCI}, MAG_{CCI}, and R are not meant to be limitations of the present invention.

By using the CCI detection mechanism described above, the present invention can provide an efficient manner to control the CCI filtering operation by detecting the existence of the CCI, and therefore can achieve better signal performance. It should be noted the present invention is not restricted to be employed in the DVB system. For example, it can also apply to any communication system that uses OFDM technique.

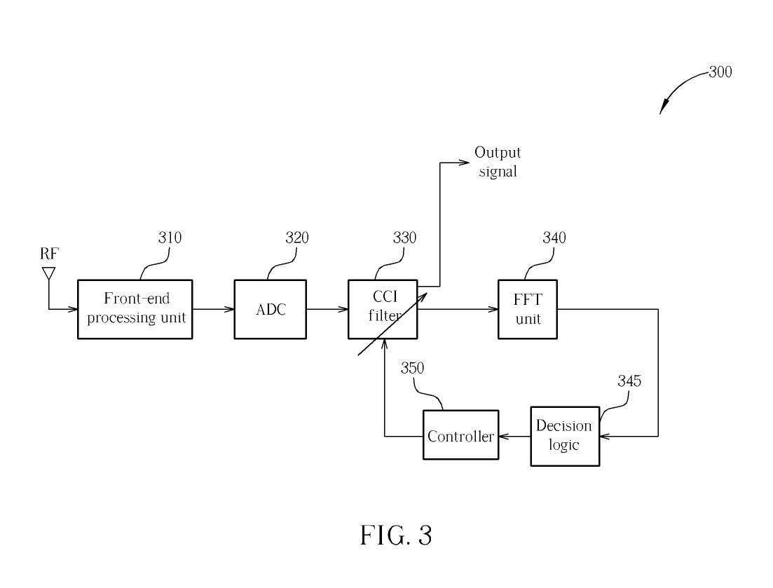

Please refer to FIG. 3. FIG. 3 illustrates a block diagram of a signal processing circuit for detecting the CCI in a DVB receiver according to a second embodiment of the invention. The signal processing circuit 300 comprises a front-end processing unit 310, an ADC 320, a CCI filter 330, an FFT unit 340, a decision logic 345, and a controller 350. Wherein the decision logic 345 is configured for detecting whether CCI exists in the communication system and generates a detection result R in a frequency domain. Then, the controller 350 selectively enables or disables the controllable CCI filter 330 according to the detection result R. In other words, an output signal is generated from the CCI filter 330 by selectively enabling or disabling an CCI filtering operation for filtering out the CCI of the received signal. The decision logic 345 in

FIG. 3 can be implemented using the circuit components shown in FIG. 1, such as functional blocks 150, 160, and 170. However, any circuit configuration capable of detecting the CCI in a frequency domain and then selectively enabling or disabling the CCI filtering operation (i.e., the controllable CCI filter 330) according to the CCI detection result can be employed in the decision logic 345 and the controller 350. These alternative designs also obey the spirit of the present invention, and fall in the scope of the present invention. Since other operation of the signal processing circuit 300 in FIG. 3 is approximately the same with that of the signal processing circuit 100 in FIG. 1, the related detail is not repeated here for brevity.

Please note that the circuit configuration respectively shown in FIG. 1 and FIG. 3 are for illustrative purposes only, and are not meant to be limitations of the present invention. In addition, in the aforementioned embodiments, the method of measuring the approximate signal power is not restricted to calculate a summation of the absolute values of FFT outputs over observed OFDM symbol length as mentioned above. The magnitude of the threshold CCI_thrd is not meant to be a limitation of the present invention. Any method that can derive the approximate value of a signal power of the signal (such as summation of the square of the FFT output) and/or calculate a ratio between the DVB signal and the CCI signal obeys the spirit of the invention falls within the scope of the invention.

Those skilled in the art will readily observe that numerous modifications and alterations of the device and method may be made while retaining the teachings of the invention.

What is claimed is:

1. A method for processing signals transmitted via a communication system, comprising:
measuring a first parameter associated with a signal power of a first frequency band of a received signal;
measuring a second parameter associated with a signal power of a second frequency band of the received signal, wherein the first frequency band and the second frequency band are overlapped;
comparing the first parameter with the second parameter to generate a comparison result; and
detecting whether co-channel interference (CCI) exists in the communication system according to the comparison result in order to generate a detection result.

2. The method of claim 1, wherein the communication system is an Orthogonal Frequency-Division Multiplexing (OFDM) communication system.

3. The method of claim 2, wherein the OFDM communication system is a digital video broadcasting (DVB) system.

4. The method of claim 1, wherein both the first frequency band and the second frequency band are portions of a signal band of the communication system.

5. The method of claim 1, further comprising:
generating an output signal by selectively enabling or disabling a CCI filtering operation for filtering out the CCI of the received signal according to the detection result.

6. A device for processing signals transmitted via a communication system, comprising:
a first evaluation unit, for measuring a first parameter associated with a signal power of a first frequency band of a received signal;
a second evaluation unit, for measuring a second parameter associated with a signal power of a second frequency band of the received signal, wherein the first frequency band and the second frequency band are overlapped;
a comparator, coupled to the first evaluation circuit and the second evaluation circuit, for comparing the first parameter with the second parameter to generate a comparison result; and
a decision unit, coupled to the comparator, for detecting whether co-channel interference (CCI) exists in the communication system according to the comparison result in order to generate a detection result.

7. The device of claim 6, wherein the communication system is an Orthogonal Frequency-Division Multiplexing (OFDM) communication system.

8. The device of claim 7, wherein the OFDM communication system is a digital video broadcasting (DVB) system.

9. The device of claim 6, wherein both the first frequency band and the second frequency band are portions of a signal band of the communication system.

10. A device for processing signals transmitted via a communication system, comprising:
a decision logic, for detecting whether co-channel interference (CCI) exists in the communication system to generate a detection result in a frequency domain; and
a controller, coupled to the decision unit, for generating an output signal by selectively enabling or disabling a CCI filtering operation for filtering out the CCI of a received signal according to the detection result.

11. The device of claim 10, wherein the communication system is an Orthogonal Frequency-Division Multiplexing (OFDM) communication system.

12. The device of claim 11, wherein the OFDM communication system is a digital video broadcasting (DVB) system.
